(19) United States
(12) Patent Application Publication
(10) Pub. No.: US 2010/0221867 A1
(43) Pub. Date: Sep. 2, 2010

(54) LOW COST SOI SUBSTRATES FOR MONOLITHIC SOLAR CELLS

(75) Inventors: Stephen W. Bedell, Yorktown Heights, NY (US); Joel P. de Souza, Yorktown Heights, NY (US); Keith E. Fogel, Yorktown Heights, NY (US); Harold J. Hovel, Yorktown Heights, NY (US); Daniel A. Inns, Yorktown Heights, NY (US); Jeehwan Kim, Yorktown Heights, NY (US); Devendra K. Sadana, Yorktown Heights, NY (US); Katherine L. Saenger, Yorktown Heights, NY (US); Ghavam G. Shahidi, Yorktown Heights, NY (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 12/436,249

(22) Filed: May 6, 2009

(51) Int. Cl. H01L 31/0376; H01L 21/762

(52) U.S. Cl. 438/96; 438/479; 257/E31.048; 257/E21.565

(57) ABSTRACT

A lost cost method for fabricating SOI substrates is provided. The method includes forming a stack of p-type doped amorphous Si-containing layers on a semiconductor region of a substrate by utilizing an evaporation deposition process. A solid phase recrystallization step is then performed to convert the amorphous Si-containing layers within the stack into a stack of p-type doped single crystalline Si-containing layers. After recrystallization, the single crystalline Si-containing layers are subjected to anodization and at least an oxidation step to form an SOI substrate. Solar cells and/or other semiconductor devices can be formed on the upper surface of the inventive SOI substrate.

### FIELD OF THE INVENTION

The present invention relates to semiconductor structures and a method of fabricating the same. More particularly, the present invention relates to a low cost semiconductor-on-insulator (SOI) substrate that can be used in a variety of semiconductor applications including, for example, as a substrate for a solar or photovoltaic cell. The present invention also provides a method of fabricating a solar cell utilizing the inventive SOI substrate as well as a solar cell including the same.

### BACKGROUND OF THE INVENTION

A solar cell or photovoltaic cell is a device that converts sunlight directly into electricity by the photovoltaic effect. Sometimes the term “solar cell” is reserved for devices intended specifically to capture energy from sunlight, while the term “photovoltaic cell” is used when the source is unspecified. Assemblies of cells are used to make solar panels, solar modules, or photovoltaic arrays.

The out voltage of a solar cell is limited by the band energy structure of its semiconductor structure, such that it is less than one volt for silicon based cells. Photovoltaic generators of higher voltages can be obtained by series association of cells. Each cell has to be individually electrically isolated from the others. When individual cells are associated they are typically mounted on an electrical insulator material and interconnected by external wiring.

Semiconductor-on-insulator (SOI) substrates provide a material that typically consists of a single crystalline silicon film (typically, but not necessarily always, thinner than 100 nm) isolated from a bulk substrate by an interposed oxide, e.g., a buried oxide, BOX. An SOI substrate allows the realization of monolithic and electrically isolated solar cells. Furthermore, it is possible to realize parallel association of identical arrays of series connected cells to provide higher current at a same voltage. These photovoltaic generators can be used in battery charge systems or to feed power to any other system in which the input voltage matches its output voltage.

One fundamental problem associated with the monolithic integration of solar cells is the cost of the SOI substrate. Two major processes are known and are presently employed to fabricate SOI substrates. One of the known processes of fabricating SOI substrates is an implantation process refer to as Separation by Implantation of Oxygen, e.g., SIMOX. The other major process known for fabricating SOI substrates is by bonding and layer transfer. Both of these known processes of fabricating SOI substrates provide a SOI material of excellent quality however, they are both relatively costly.

A simpler process of fabricating SOI substrates at a lower cost as compared with the known processes described above is disclosed, for example, in U.S. Ser. No. 12/170,459, filed Jul. 10, 2008, entitled “Formation of SOI by Oxidation of Silicon with Engineered Porosity Gradient”. In this prior art method, an SOI substrate is formed by anodization of stacked epitaxial grown layers of different p-type dopant concentration in order to obtain a depth distribution of the porosity. Subsequent oxidation followed by a high temperature anneal (on the order of 1100° C.) converts the buried layer of highest porosity (i.e., the buried layer of highest doping concentration) into a buried oxide layer. In this prior art method, the layer closest to the surface where the porosity is the lowest, is converted to a crystalline silicon layer, e.g., the SOI layer, of a now formed SOI substrate.

### SUMMARY OF THE INVENTION

The present invention provides an alternative method of fabricating low cost SOI substrates that can be used in a variety of semiconductor applications including, but not limited to, as a substrate for a solar cell or photovoltaic cell. It should be noted that the structure of the solar cell and the photovoltaic cell provided by the invention are the same; the difference in terminology being the type of source impinging upon the cell.

In particular, the present invention provides a method in which a stack containing a plurality of amorphous Si-containing layers is formed on a major surface of a semiconductor substrate, rather than a stack of epitaxial Si-containing layers as disclosed in U.S. Ser. No. 12/170,459, filed Jul. 10, 2008. In the present invention, the amorphous Si-containing layers within the stack can be formed by utilizing an evaporation deposition process. The evaporation deposition process used in the present invention may include, for example, e-beam deposition, co-evaporation deposition, plasma enhanced chemical vapor deposition (PECVD) and sputtering. Doping of the amorphous Si-containing layers can be performed in-situ or ex-situ by ion implantation, gas phase doping, gas phase immersion and/or outdiffusion from a sacrificial dopant source layer. In a highly preferred embodiment of the present invention, the p-type doped amorphous Si-containing layers are formed by a co-evaporation method wherein simultaneous evaporation of a Si-containing source material and p-type dopant atoms (e.g., boron, gallium, indium, with boron being preferred) is employed. Solid phase recrystallization of the amorphous Si-containing layers is then performed using the underlying semiconductor substrate as a recrystallization template. During this step of the present invention, the p-type doped amorphous Si-containing layers are converted into p-type doped single crystalline Si-containing layers. After recrystallization, the single crystalline Si-containing layers are subjected to anodization and at least an oxidation step to form an SOI substrate.

The SOI substrate fabricated in accordance with the present invention can be directly used as a substrate for a semiconductor device, such as a thin film solar cell or a photovoltaic cell, or it can be used as a template for growth of silicon or different crystalline semiconductor materials for thicker film cells or multi-junction cells.

In general terms, the method of the present invention includes:
forming a stack including a plurality of p-type doped amorphous Si-containing layers onto a major surface of a semiconductor region of a substrate, said stack including at least a first p-type doped amorphous Si-containing layer having a dopant concentration of at least 1×10¹⁹ atoms/cm³ or greater, and a second p-type doped amorphous Si-containing layer located on an upper surface of the first p-type doped amorphous Si-containing layer and having a dopant concentration less than said first p-type doped amorphous Si-containing layer;
performing solid phase epitaxy on said stack of p-type doped amorphous Si-containing layers to convert said stack into a stack of single crystalline Si-containing layers including at least a first p-type doped single crystalline Si-containing layer having a dopant concentration of at least 1×10¹⁹ atoms/cm³ or greater and a second p-type doped single crystalline Si-containing layer located on an upper surface of the first p-type doped single crystalline Si-containing layer and having a dopant concentration less than said first p-type doped single crystalline Si-containing layer; and
processing the substrate including the stack of single crystalline Si-containing layers to form a buried oxide layer selectively by oxidizing at least portions of the first p-type doped single crystalline Si-containing layer covered by the second p-type doped single crystalline Si-containing layer and annealing the substrate to form a monocrystalline semiconductor layer from the second doped single crystalline Si-containing layer, wherein the buried oxide layer separates the overlying monocrystalline semiconductor layer from the underlying semiconductor region.

The inventive process provides an SOI substrate including a silicon-containing monocrystalline semiconductor layer separated from an underlying semiconductor region by a buried oxide layer having a thickness less than or equal to about 100 nm, the buried oxide layer having a surface roughness having a root mean square value of less than about one nanometer.

In one embodiment of the present invention, the processing includes a step of subjecting the substrate including the stack of single crystalline Si-containing layers to anodization to selectively form a porous Si-containing layer of higher porosity from the first p-type doped single crystalline layer and a porous Si-containing layer of a lower porosity from the second p-type doped Si-containing layer prior to oxidizing the porous Si-containing layers to form a buried oxide layer and a monocrystalline semiconductor layer. Porosity is defined herein as the ratio of the specific weight of the porous Si-containing material and the specific weight of the original ‘non-porous’ Si-containing material. In this embodiment of the invention, the buried oxide layer is formed by fully oxidizing the layer of higher porosity and then annealing is performed at a high temperature to convert the layer of lower porosity to the monocrystalline semiconductor layer.

In another embodiment of the present invention, the stack of amorphous Si-containing layers includes a non-highly p-type doped amorphous Si-containing layer having a dopant concentration less than the first p-type doped amorphous Si-containing layer interposed between the semiconductor region of the underlying substrate and the first p-type doped amorphous Si-containing layer. In yet a further embodiment of the present invention, a highly p-type doped amorphous Si-containing layer is formed onto a major surface of the second p-type doped amorphous Si-containing layer. When the highly p-type doped amorphous Si-containing layer is present, it is converted into an overlying oxide layer, which can be removed in a subsequent processing step. It is observed that the presence of the highly p-type doped amorphous Si-containing layer atop the second p-type doped amorphous Si-containing layer protects the second p-type doped amorphous Si-containing layer from pitting during anodization and reduces the defect density in the monocrystalline semiconductor layer which results from the second p-type doped Si-containing layer.

In an even further embodiment of the present invention, the stack of p-type doped amorphous Si-containing layers includes a plurality of alternating layers of the first and second p-type doped amorphous Si-containing layers located atop each other. In this embodiment, it is possible to form an SOI substrate including a plurality of alternating layers of buried oxide and monocrystalline semiconductor material vertically stacked upon each other.

The present invention also provides a semiconductor structure including the SOI substrate produced using the inventive process and at least one semiconductor device located on a surface thereof. In one embodiment of the invention, the at least one semiconductor device is a solar cell or a photovoltaic cell. The inventive structures including at least a solar cell or at least one photovoltaic cell atop the inventive SOI substrate have a voltage output ranging from 0.5 to 120 V.

The solar cell or photovoltaic cell of the present invention includes alternating layers of doped Si-containing materials stacked vertically upon an uppermost monocrystalline semiconductor layer of the inventive SOI substrate. The doped Si-containing layers may all be crystalline, all be amorphous or be a mixture of amorphous and crystalline Si-containing materials. The alternating layers of Si-containing materials typically include a p+ Si-containing material located on a surface of the monocrystalline semiconductor layer, a p− Si-containing material located on a surface of the p+ Si-containing material, and an n+Si-containing material located on a surface of the p− Si-containing material.

### BRIEF DESCRIPTION OF THE DRAWINGS

FIG. 1 is a pictorial representation (through a cross sectional view) illustrating an initial substrate that can be employed in one embodiment of the present invention.

FIGS. 2A-2C are pictorial representations (through cross sectional views) illustrating the substrate of FIG. 1 after forming a stack of p-type doped amorphous Si-containing layers on a major surface thereof.

FIG. 3 is a pictorial representation (through a cross sectional view) illustrating the structure shown in FIG. 2A after performing solid phase epitaxy.

FIG. 4 is a pictorial representation (through a cross sectional view) illustrating the structure shown in FIG. 3 after performing porosification.

FIG. 5 is a pictorial representation (through a cross sectional view) illustrating the structure shown in FIG. 4 after performing oxidation, annealing and removing the surface oxide layer.

FIG. 6A is a scanning electron micrograph (SEM) of a cross section of the porous structure formed after porosification, while FIG. 6B is an SEM of a cross section after oxidation, high temperature annealing and removal of the surface oxide layer.

FIG. 7 is a pictorial representation (through a cross sectional view) illustrating an SOI substrate that is formed utilizing the structure shown in FIG. 2C following solid phase epitaxy, porosification, oxidation, annealing and after surface oxide removal.

FIGS. 8A and 8B are pictorial representations (through cross sectional views) illustrating the formation of a plurality of doped Si-containing materials atop the SOT substrates shown in FIG. 5 and FIG. 7, respectively.

FIG. 9 is a pictorial representation (through a cross sectional view) illustrating the structure shown in FIG. 8A after solar cell fabrication in accordance with an embodiment of the invention.

### DETAILED DESCRIPTION OF THE INVENTION

The present invention, which provides a simple and low cost method of fabricating SOI substrates that can be used in various semiconductor applications, including in solar cell or photovoltaic cell fabrication, will now be described in greater detail by referring to the following discussion and drawings that accompany the present application. It is noted that the drawings of the present application are provided for illustrative purposes only and, as such, the drawings are not drawn to scale.

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present In contrast, when an element is referred to as being “directly connected” or “directly coupled” to another element, there are no intervening elements present.

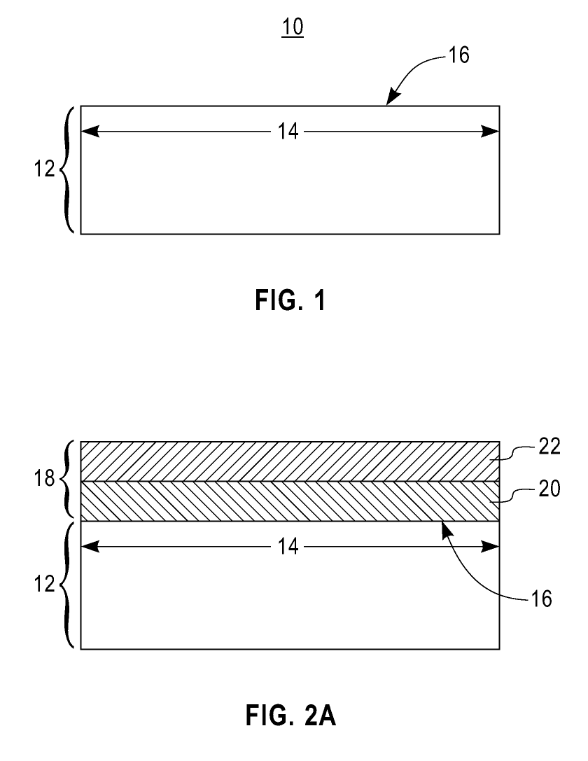

Reference is first made to FIGS. 1-5 which illustrate the basic processing steps that are employed in the present invention for fabricating an SOI substrate. As used herein the term “semiconductor-on-insulator substrate” refers to a structure in which an active semiconductor region containing monocrystalline semiconductor material such as silicon or an alloy of silicon with another semiconductor material, such as for example, silicon germanium (“SiGe”), silicon carbon (“SiC”) overlies a bulk semiconductor region of a substrate and is separated from the bulk semiconductor region of the substrate by a buried oxide (“BOX”) layer. Once the SOI substrate is fully formed, active semiconductor devices, such as transistors, diodes, solar cells, photovoltaic cells, for example, can have portions fabricated upon the active semiconductor region.

Reference is first made to FIG. 1 which is a cross sectional view of an initial structure 10 that can be employed in the present invention. As illustrated, the initial structure 10 includes a substrate 12 including a monocrystalline semiconductor region 14 having a major surface 16 that is exposed. The underlying monocrystalline semiconductor region 14 of substrate 12 typically is a bulk semiconductor region of a semiconductor substrate. Alternatively, the underlying monocrystalline semiconductor region 14 can be a monocrystalline semiconductor region of a substrate other than a bulk semiconductor region. The underlying semiconductor region 14 can have a dopant type, i.e., n-type or p-type, and concentration, e.g., n⁻, n, n⁺, p⁻, p or p⁺, such as may be selected to be compatible with the fabrication of semiconductor devices in the SOI substrate to be completed by the method of fabrication. In a preferred embodiment the underlying semiconductor region 14 of substrate 12 is doped with a p-type dopant (i.e., one of B, Ga and In, preferably B). The dopant concentration of this preferred embodiment is typically less than 1×10¹⁹ atoms/cm³.

Doping can be achieved utilizing any conventional process including, for example, ion implantation, gas phase doping and outdiffusion from a p-type dopant surface material which is selectively removed following the outdiffusion process.

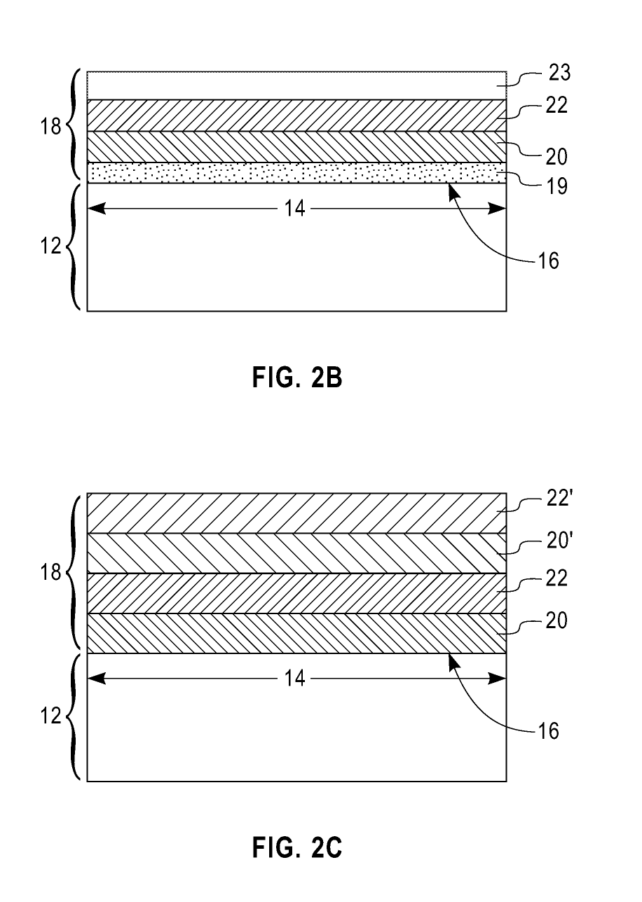

Next, and as shown in FIG. 2A, FIG. 2B and FIG. 2C, a stack 18 including a plurality of p-type doped amorphous Si-containing layers is formed onto the major surface 16 of the semiconductor region 14 of the substrate 12 shown in FIG. 1 Although the number of layers contained in stack 18 may vary, each stack 18 that is formed in the present invention includes at least a first p-type doped amorphous Si-containing layer 20 having a dopant concentration of at least 1×10¹⁹ atoms/cm³ or greater, preferably from 1×10¹⁹ atoms/cm³ to 1×10²⁰ atoms/cm³, and a second p-type doped amorphous Si-containing layer 22 located on an upper surface of the first p-type doped amorphous Si-containing layer 20. In accordance with the present invention, the second p-type doped amorphous Si-containing layer 22 has a dopant concentration that is less than said first p-type doped amorphous Si-containing layer 20. Typically, the second p-type doped amorphous Si-containing layer has a dopant concentration of less than 1×10¹⁹ atoms/cm³, with a dopant concentration from 1×10¹⁶ atoms/cm³ to 1×10¹⁸ atoms/cm³ being even more typical. In FIG. 2A, layers 20 and 22 are representative of stack 18.

In FIG. 2B, stack 18 includes, from bottom to top, layers 19, 20, 22 and 23. Layer 19 of stack 18 shown in FIG. 2B is a non-highly p-type doped amorphous Si-containing that is located between the semiconductor region 14 of substrate 12 and the first p-type doped amorphous Si-containing layer 20. The non-highly p-type doped amorphous Si-containing layer 19 has a dopant concentration that is less than the dopant concentration of the first p-typed doped amorphous Si-containing layer 20. Typically, the doped concentration within layer 19 is less than 1×10¹⁹ atoms/cm³, with a dopant concentration of from 1×10¹⁷ atoms/cm³ to 1×10¹⁸ atoms/cm³ being even more typical. It is observed that layer 19 is not typically employed when the semiconductor region 14 of substrate 12 has a dopant concentration of less than 1×10¹⁹ atoms/cm³. Layer 23, which is located atop layer 22, is a highly p-type doped amorphous Si-containing layer which has a doping concentration of about 1×10²⁰ atoms/cm³ or greater, with a dopant concentration from 1×10²⁰ atoms/cm³ to 2×10²⁰ atoms/cm³ being more preferred. Layer 23 is optional; however its presence protects the second p-type doped amorphous Si-containing layer 22 from pitting during an anodization process that is performed during a further processing step of the invention.

FIG. 2C shows an embodiment in which stack 18 includes a plurality of alternating layers of the first and second p-type doped amorphous Si-containing layers vertically stacked upon each other. In particular, stack 18 shown in FIG. 2C includes, from bottom to top, a first p-type doped amorphous Si-containing layer 20, a second p-type doped amorphous Si-containing layer 22, another first p-type doped amorphous Si-containing layer 20′, and another second p-type doped amorphous Si-containing layer 22′. Layers 19 and 23 can optionally be used in this embodiment of the present invention as well. The embodiment shown in FIG. 2C allows for fabricating an SOI substrate having multiple alternating layers of buried oxide and monocrystalline semiconductor stacked vertically atop each other

Notwithstanding the number of p-type dopant layers within stack 18 each p-type dopant layer is amorphous and includes a Si-containing semiconductor material selected from Si, SiGe, SiC, SGeC and other like semiconductor materials that include silicon. Preferably, each of the Si-containing layers within stack 18 is composed of silicon.

Stack 18, e.g., the plurality of p-type doped amorphous Si-containing layers, is formed utilizing an evaporation deposition process selected from the group consisting of e-beam, co-evaporation deposition, plasma enhanced chemical vapor deposition, and sputtering. In order to ensure that amorphous Si-containing layers are formed, the deposition is performed at a temperature of about 500° C. or less. Preferably, the amorphous Si-containing layers of stack 18 are formed by high vacuum e-beam deposition. In the evaporation deposition processes mentioned above, deposition is performed at a pressure of less than about 1×10⁻⁷ Torr, with a deposition pressure of from 1×10⁻⁸ Torr to 1×10⁻¹⁰ Torr being more preferred. In a highly preferred embodiment of the present invention, the p-type doped amorphous Si-containing layers are formed by a co-evaporation method wherein simultaneous evaporation of a Si-containing source material and p-type dopant atoms (e.g., boron, gallium, indium, with boron being preferred) is employed.

Each amorphous Si-containing layer present in stack 18 is doped in-situ or ex-situ, with in-situ doping being preferred. Examples of doping processes that can be used in the present invention include, but are not limited to ion implantation, gas phase in-situ doping, gas phase immersion and/or outdiffusion from a sacrificial dopant source layer. When ex-situ doping is used, doping occurs after depositing each amorphous Si-containing layer within stack 18.

When ion implantation is used in creating the p-type doped layers, p-type dopant ions are implanted using an energy of greater than 1 keV, with an energy from 10 keV to 30 keV being more typical. The ion implantation may occur at nominal room temperature (i.e., 20°-30° C.) or at a substrate temperature greater than 35° C. with a temperature from 100° C. to 300° C. being more typical. The p-type dopant is performed to a proper dose and energy after each individual layer is formed.

When plasma immersion is used to introduce the p-type dopants, the plasma immersion is performed by first providing a plasma that includes the p-type dopant. The introduction of the p-type dopant is then performed utilizing plasma immersion conditions that are capable of forming the p-type dopant Si-containing layer. Typically, the plasma immersion is performed utilizing standard operating conditions to achieve similar ion concentrations as stated above in connection with each of the amorphous Si-containing layers within stack 18.

When a sacrificial dopant source material containing a p-type dopant is used in forming the p-type amorphous Si-containing layers of stack 18, a sacrificial material containing the p-type dopants is first deposited on the surface of a deposited amorphous Si-containing layer of stack IS. The sacrificial dopant source material including the p-type dopant may comprise a boron doped silicate glass, for example. The p-type dopant is present in the sacrificial material in amounts that achieve desired concentrations of the p-type dopants in the amorphous Si-containing layer of stack 18. The sacrificial dopant source material can be deposited by any conventional deposition process such as, for example, chemical vapor deposition, plasma enhanced chemical vapor deposition, evaporation, spin-on coating, and physical vapor deposition. The thickness of the sacrificial dopant source material containing the p-type dopants may vary. After depositing the sacrificial dopant source material, the material layer including the p-type dopants is then annealed under conditions that are effective for causing diffusion of the dopants from the sacrificial material layer into the underlying Si-containing layer. The annealing may be performed in a furnace or in a chamber in which the dopant source material layer was initially deposited. The anneal step is performed at a temperature of greater than about 550° C. with a temperature from 900° C. to 1100° C. being more typical. In addition to the specific types of annealing mentioned above, the present invention also contemplates rapid thermal annealing, spike annealing, laser annealing and other like annealing processes that are capable of performing dopant diffusion. After diffusion, the dopant source material layer is typically stripped from the surface of the structure utilizing a conventional stripping process.

Another technique that can be used in forming the p-type dopant amorphous Si-containing layers is to introduce the p-type dopant into the layer by in-situ gas phase doping. In such a process, the doping may occur after forming a particular amorphous Si-containing layer by changing the precursors used in formation of layer Si-containing layer to include p-type dopants.

The thickness of each amorphous Si-containing layer within stack 18 may vary depending on the desired thickness of the buried oxide layer and monocrystalline semiconductor layer to be subsequently formed. When present, amorphous Si-containing layer 19 has a thickness from 10 nm to 1000 nm, amorphous Si-containing layer 20 has a thickness from 5 nm to 200 nm, amorphous Si-containing layer 22 has a thickness from 40 nm to 500 nm, and amorphous Si-containing layer 23, if present, has a thickness from 10 nm to 50 nm. It is observed that the thickness of amorphous Si-containing layer 20 will determine the thickness of the buried oxide layer to be subsequently formed, while the thickness of the amorphous Si-containing layer 22 determines the thickness of the monocrystalline semiconductor layer to be subsequently formed.

It is further observed that in the following drawings and description, the processing steps are described utilizing the structure shown in FIG. 2A. Although such illustration and description is provided, the following processing steps can be used when additional amorphous Si-containing layers, besides layers 20 and 22, are present in stack 18.

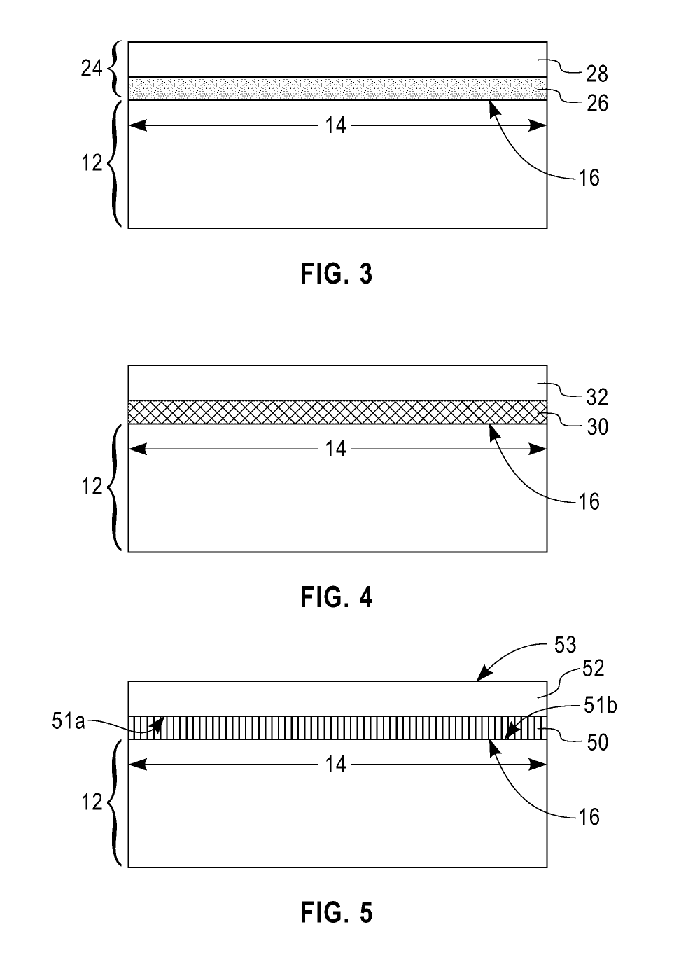

After providing stack 18 atop substrate 12, a solid phase epitaxy process is performed which converts stack 18 of p-type doped amorphous Si-containing layers into a stack 24 of single crystalline Si-containing layers. The resultant structure, including stack 24 is shown, for example, in FIG. 3. In one embodiment of the invention, stack 24 includes at least a first p-type doped single crystalline Si-containing layer 26 having a dopant concentration of at least 1×10¹⁹ atoms/cm³ or greater (note layer 26 is derived from layer 20 and, as such, it has the same dopant concentration as that layer) and a second p-type doped single crystalline Si-containing layer 28 (note layer 28 is derived from layer 22 and, as such, it has the same dopant concentration as that layer) located on a major surface of the first p-type doped single crystalline Si-containing layer 26. In accordance with the present invention, the dopant concentration of the second p-type doped Si-containing layer 28 is less than the dopant concentration of the first p-type doped single crystalline amorphous Si-containing layer 26.

The solid phase epitaxy process of the present invention converts the amorphous Si-containing layers within stack 18 into a stack in which each of the layers is a single crystalline Si-containing material. The solid phase epitaxy process may be performed by furnace annealing, rapid thermal annealing, laser annealing, electron beam annealing and other like annealing processes that are capable of recrystallization. In addition to performing the aforementioned function, the solid phase epitaxy also activates the p-type dopant atoms within each of the Si-containing layers. Specifically, solid phase epitaxy is performed in the present invention at a recrystallization temperature of greater than 450° C. utilizing the underlying semiconductor region 14 of substrate 12 as a recrystallization template, with a recrystallization temperature from 550° C. to 700° C. being more preferred. In one embodiment, a preferred recrystallization temperature is 650° C. In addition to being performed at a recrystallization temperature, the solid phase epitaxy is carried out in an inert gas. The term “inert gas” as used throughout the present application denotes an ambient including at least one of helium, argon, neon, krypton, xenon and nitrogen. Preferably, the solid phase epitaxy is performed in nitrogen or argon. The duration of the solid phase epitaxy may vary depending on the number of amorphous Si-containing layers within stack 18. Typically, the solid phase epitaxy is performed for a duration of time of greater than 30 minutes, with a duration of time of greater than 1 hour being even more typical. It is observed that the solid phase epitaxy process described above maintains the dopant profile in each of the amorphous Si-containing layers. The maintenance of dopant profile in each of the layers is critical to guarantee reproducibility of the SOI layer (e.g., the monocrystalline semiconductor layer to be subsequently formed) and the buried oxide (BOX also to be subsequently formed).

After performing the solid phase epitaxy, the structure shown in FIG. 3 is processed to form a buried oxide layer 50 selectively by oxidizing at least portions of the first p-type doped single crystalline Si-containing layer 26 covered by the second p-type doped single crystalline Si-containing layer 28 and annealing the substrate to form a monocrystalline semiconductor layer 52 from the second doped single crystalline Si-containing layer 28. These processing steps of the present invention which lead to the fabrication of an SO substrate, are shown in FIGS. 4 and 5.

Specifically, FIG. 4 illustrates the structure of FIG. 3 after performing an anozidation process. The anodization process selectively forms a first porous Si-containing layer 30 from the first p-type doped single crystalline Si-containing layer 26 and a second porous Si-containing layer 32 from the second p-type doped single crystalline Si-containing layer 28 prior to oxidizing. The first porous Si-containing layer 30 that is formed in the present invention has a greater density of porous than the second porous Si-containing layer 32. As such, the first porous Si-containing layer 30 can be referred to herein as a coarse porous Si-containing layer, while the second porous Si-containing layer 32 can be referred to herein as a fine porous Si-containing layer. Typically, the first porous Si-containing layer 30 has a porosity from 45% to 60%, while the second porous Si-containing layer 32 has a porosity from 10% to 35%.

Porous Si can be formed by electrolytic anodization in a solution containing HF. An HF-resistant electrode, such as one made of platinum, is biased negatively, and the Si substrate is biased positively. The porosity, measured in terms of the mass loss, of the resulting porous Si layer formed in the surface of a Si wafer is proportional to the electrical current density and inversely proportional to the HF concentration. The depth of a porous Si layer formed within a region of silicon can be proportional to the anodization time for a given dopant concentration and current density. The actual structure of the porous Si, however, is a very complicated function of the type and concentration of dopants and defects, in addition to the above-mentioned parameters. A common characteristic of porous Si materials is the enormous surface area associated with high-density pores: The surface area per unit volume is estimated to be 100-200 m² cm³, i.e., 100-200 square meters of surface area per each cubic centimeter in volume. The presence of this large surface area makes porous Si very susceptible to chemical reaction with an ambient gas such as oxygen. The oxidation rate of porous Si is found to be an order of magnitude higher than that of bulk Si. This makes porous Si a good candidate for oxide isolation.

In an example of an anodization process, anodization can be performed at room temperature or below room temperature in the dark, or with exposure to light by immersing the substrate with the series of single crystalline layers thereon in an electrolyte formed by hydrogen fluoride (HF) (which can be used from a typical commercial solution at a weight concentration of 49%, for example. The electrolyte can be prepared by dilution of the commercial HF solution in water to a lower concentration). The substrate (anode) is then connected to the positive electrode (anode) of a voltage source in order to hold the substrate at a constant potential and another electrode (cathode) of the voltage source is immersed in the electrolyte, the cathode typically including a material which is resistant to HF, such as platinum (Pt) or graphite, for example. Alternatively, the electrolyte can have a different composition, such as a mixture of HF with water, alcohol or ethylene glycol, for example, which can have a range of concentrations.

In one embodiment, the anodization process can be implemented by a constant current process at room temperature or below room temperature in HF at concentration of 49% in weight. Current density during anodization can range from one to 20 milliamperes per centimeter squared (mAcm⁻²). Typically anodization times can range between 10 seconds and 100 seconds. The amount of time required to perform the anodization depends upon a variety of factors, such as the dopant concentration within the Si-containing layers of stack 24, the thickness of the layers within stack 24 and the current density selected to perform the anodization. When present, the highly p-typed doped amorphous Si-containing layer 23 which is converted to a single crystalline Si-containing layer during solid phase epitaxy, aids in eliminating the formation of etch pits during anodization of the stack 24. Such pits can consume a part of the vertical height of the Si-containing layer 28 and result in structural imperfections in the SOI layer to be formed after the subsequent thermal treatment.

Following anodization, and as shown in FIG. 5 further processing is performed to oxidize the porous layer 30 to form a layer of oxide 50 in its place and eliminating the fine porous in the layer 32 to render them single crystalline, e.g., monocrystalline silicon with its natural density. In FIG. 5, reference numeral 52 denotes the monocrystalline semiconductor layer formed atop the buried oxide 50. The substrate may also be held at a high temperature for a number of hours in order to “anneal” the substrate, i.e., such as for the purpose of producing a high quality monocrystalline semiconductor layer, healing crystal defects in the single crystal layer and the underlying substrate. The annealing process may also improve the density and other characteristics, e.g., dielectric strength of the oxide layer 50.

The oxidation step of the present invention is a dry thermal oxidation process that is performed at a temperature from 400+ C. to 1150° C., with a temperature from 800° C. to 1050° C. being more highly preferred. Moreover, the oxidation step of the present invention is carried out in an oxidizing ambient which includes at least one oxygen-containing gas such as O₂, NO, N₂O, ozone, air and other like oxygen-containing gases. The oxygen-containing gas may be admixed with each other (such as an admixture of O₂ and NO), or the gas may be diluted with an inert gas such as He, Ar, N₂, Ex, Kr, or Ne. When a diluted ambient is employed, the diluted ambient contains from 0.5% to 100% of oxygen-containing gas, the remainder, up to 100%, being inert gas. The oxidation step may be carried out for a variable period of time that typically ranges from 10 minutes to 180 minutes at 800° C. to 1050° C., with a time period from 30 minutes to 180 minutes being more highly preferred. The oxidation step may be carried out at a single targeted temperature, or various ramp and soak cycles using various ramp rates and soak times can be employed.

In some embodiments of the present invention, an inert gas carrying water vapor, O₂ carrying water vapor, or steam can be used in place of the dry oxidation process mentioned above. When such “wet” oxidations are performed, they are typically performed at a temperature from 400° C. to 1000° C., with a temperature from 400° C. to 800° C. being more highly preferred. The “wet” oxidation step using the aforementioned alternative gases is advantageous in that it converts the porous Si into an oxide at an accelerated rate before it coalesces into large Si grains.

The oxidized product is then annealed at a temperature of greater than 1200° C., preferably from 1250° C. to 1325° C., in an atmosphere of inert gas (e.g., N₂, Ar, Hie and other noble gases and mixtures thereof) mixed with oxygen in a concentration in the range from 2% to 20%. A chlorine-containing compound such as, for example, HCl, 1-1-1 trichloroethane (TCA) and trans-1,2 dichloroethylene (TransLC), can also be added. In one embodiment of the invention, the annealing step is performed at 1320° C. for 5 hours in Ar mixed with 2% oxygen.

During the oxidation and annealing steps, the course porous Si-containing layer 30 is converted into a buried oxide 50, while the fine porous Si-containing layer 32 is converted to a monocrystalline semiconductor layer 52. At this point of the present invention any surface oxide (not shown) that is formed during the inventive process can be removed utilizing a conventional etching process that selectively removes oxide.

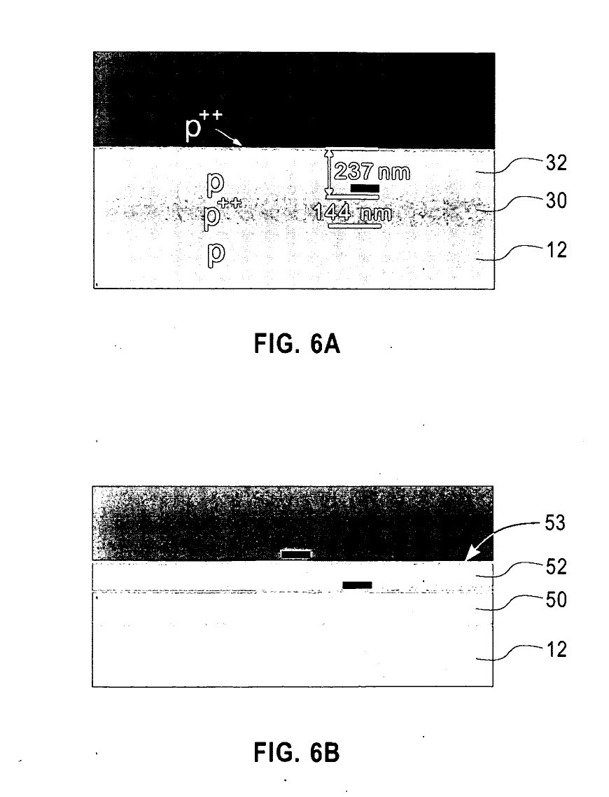

FIG. 6A is a scanning electron micrograph (SEM) of a cross section of the porous structure formed after porosification in accordance with one embodiment of the invention, while FIG. 6B is an SEM of a cross section after oxidation and high temperature annealing in accordance with the present invention.

The resultant SOI (see FIG. 5) of the present invention is a semiconductor-on-insulator substrate 48 having a high quality BOX layer 50 with upper and lower major surfaces 51a, 51b which are well-controlled in distance from the exposed major surface 53 of the monocrystalline semiconductor layer 52. The thickness of the monocrystalline semiconductor layer 52 that results is slightly smaller than the thickness of the single crystalline Si-containing layer 28, since a fraction of the mass was removed for the formation of its fine porous structure and eventually due to oxidation of a top portion of this layer. Using the techniques described herein, the monocrystalline semiconductor layer 52 can have a thickness ranging upwards from about 5 nm. Large thicknesses can be achieved as well, such that a semiconductor layer 52 having a thickness of 200 nm or more can be achieved.

The thickness of the BOX layer 50 can also be controlled very well. Using the techniques described herein, the BOX layer 50 can have a thickness ranging upwardly from about 10 nm. Large thicknesses are achievable by the techniques described herein, such that a BOX layer 50 having a thickness of 200 nm or more can be achieved. The thickness of the final BOX layer 50 is determined primarily by the thickness of the first p-type doped amorphous Si-containing layer prior to being made single crystalline and porous. The thickness of the final BOX layer 50 is also determined in part by the density of the porous semiconductor layer 30 from which it is formed by oxidation. Semiconductor oxide material, e.g., silicon dioxide, formed by oxidizing semiconductor material such as silicon, occupies a greater volume than the volume occupied by pure semiconductor material, since in each molecule of the semiconductor oxide material two oxygen atoms join each silicon atom of the original semiconductor material. Therefore, a layer of semiconductor material of normal density expands during oxidation to a greater volume and becomes a thicker oxide layer than the initial semiconductor layer. However, when the semiconductor material begins as a relatively porous layer, the expansion during oxidation occurs internally within the voids of the porous semiconductor layer, such that the thickness of the semiconductor oxide layer may not be much greater than the thickness of the initial semiconductor layer. In fact, the thickness of the semiconductor oxide layer may be the same as or less than the thickness of the initial semiconductor layer.

The volume occupied by pure silicon dioxide is greater than the volume occupied by pure silicon by a ratio of 2.25:1. Thus, when the proportion of silicon that remains within each porous silicon region is greater than 1/2.25 (i.e., the remaining silicon mass within the volume of the porous silicon region is greater than about 44% of the original mass), the resulting silicon dioxide expands. Another way that this can be stated is the following: the resulting silicon dioxide expands to occupy a larger volume than an original layer of silicon when porosity is less than 56%, that is, when the amount of mass removed from the defined volume of the porous silicon region is less than 56% of the starting mass. In general, the degree of porosity is higher when the boron concentration is higher, and the degree of porosity is lower when the boron concentration is lower. Also, in general, higher porosity can be achieved when the current density of the anodization process is higher. Conversely, lower porosity is achieved when the current density is lower.

As the upper and lower boundaries of the first p-type doped Si-containing layer are generally better controlled than, i.e., generally sharper than those which can defined by implantation over the surface of a wafer, the depths of the major surfaces of the buried oxide (“BOX”) layer 50 below the exposed major surface of layer 52 are also controlled well. Moreover, the major surfaces of the BOX layer 50 have surface roughness that compares to that of a BOX layer formed by implantation of oxygen and annealing. Thus, the major surfaces of the BOX layer 50 can have a root mean square surface roughness of as little as one nm or less. The amplitude of the roughness of the BOX layer 50 can be less than 3.5 nm. With appropriate process control, the surface roughness can reach a root mean square value of 0.40 nm.

The more precise control over the locations of the surfaces of the BOX layer allows processing tolerances for the thickness of the BOX layer 50 to be tightened. With the thickness of the BOX layer 50 more precisely controlled, the nominal thickness of the BOX layer can be reduced. Thus, in one embodiment, the thickness of the BOX layer 50 can be as small as 10 nm or less. The distance separating the overlying monocrystalline semiconductor layer 52 from the underlying semiconductor region 14 can be controlled to 10 nm or less.

However, the relatively small thickness of the BOX layer does not impact the dielectric strength of the BOX layer. Given a BOX layer thickness of 50 nm or less, the high quality of the BOX layer makes it possible to attain a dielectric strength of at least one megavolt per centimeter (MV cm⁻¹). When the fabrication process is appropriately controlled, a dielectric strength of greater than eight megavolts per centimeter can be achieved and reduce the density of electrical shorts between the SOI layer and the underlying semiconductor region 100 across the BOX layer to less than about 5 cm⁻² or even less than 2 cm⁻², despite the BOX layer being thin at less than or equal to about 50 nanometers in thickness.

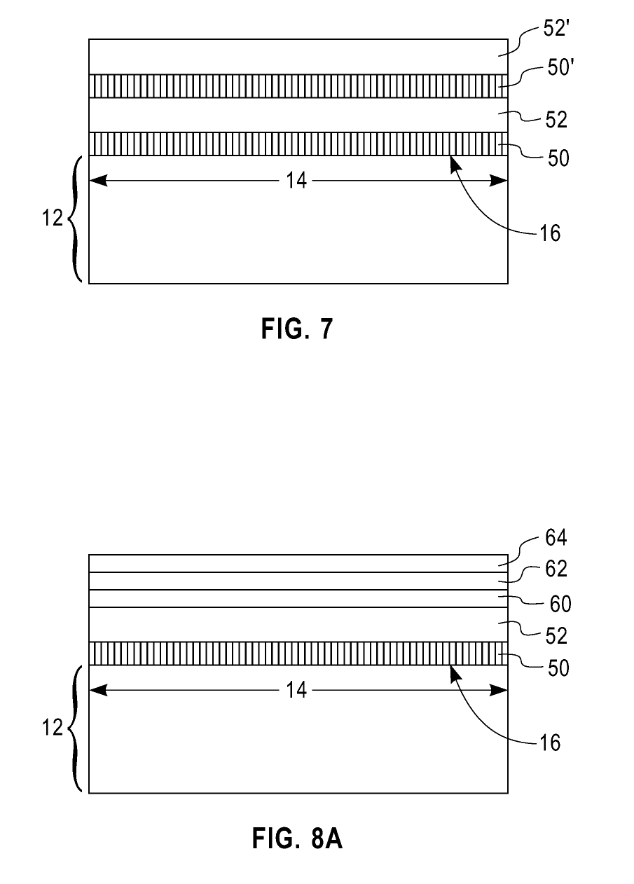

Reference is now made to FIG. 7 which is a pictorial representation (through a cross sectional view) illustrating an SOI substrate that is formed utilizing the structure shown in FIG. 2C following solid phase epitaxy, porosification and annealing as described above. In the SOI substrate shown in FIG. 7, a buried oxide layer 50′ and monocrystalline semiconductor layer 52′ are shown vertically stacked over buried oxide layer 50 and monocrystalline semiconductor layer 52. It is noted that although two buried oxide layers and two monocrystalline semiconductor layers are shown, the present invention can also be employed to provide an SOI substrate including a plurality of vertically stacked and alternating layers of buried oxide and monocrystalline semiconductor material.

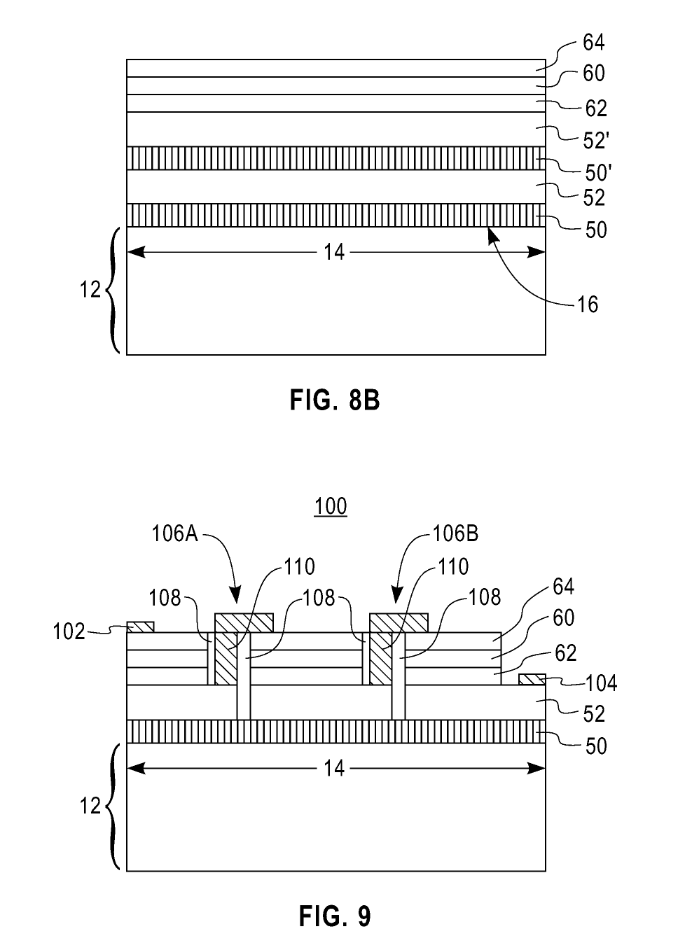

FIGS. 8A and 8B are pictorial representations (through cross sectional views) illustrating the formation of a plurality of doped Si-containing materials atop the SOI substrates shown in FIG. 5 and FIG. 7, respectively. In particular, FIGS. 8A and 8B illustrate a p+ Si-containing material 60 having a dopant concentration from 1×10¹⁷ atoms/cm³ to 1×10²⁰ atoms/cm³ located atop the upper most monocrystalline semiconductor layer of the inventive SOI substrate, a p− Si-containing material 62 having a dopant concentration from 1×10¹⁴ atoms/cm³ to 1×10¹⁷ atoms/cm³ located atop the p+ Si-containing material 60, and an n+ Si-containing material 64 having a dopant concentration from 1×10¹⁸atoms/cm³ to 1×10²⁰ atoms/cm³ located atop the p− Si-containing material 62.

The doped Si-containing materials shown in FIGS. 8A and 8B can all be crystalline all be amorphous, or some can be crystalline and some can be amorphous. For example, the present invention contemplates a structure including layers 60 and 62 being crystalline and layer 64 being amorphous, and a structure including layers 64 and 62 being amorphous and layer 60 being crystalline. The Si-containing materials may include the same or different Si-containing semiconductor materials as mentioned above in respect to the p-type doped amorphous Si-containing layers of stack 18.

The doped Si-containing materials shown in FIGS. 8A and 8B are formed by either epitaxy growth or using the amorphous deposition process mentioned above. Doping of the layers occurs either in-situ during the deposition of each doped Si-containing material, or immediately following the deposition of an undoped Si-containing material. In some embodiments, the deposition of the amorphous Si-containing material may be followed by a solid phase epitaxy process. It is noted that when Si-containing materials are formed by amorphous deposition, followed by solid phase epitaxy, the resultant crystalline material maintains the dopant profile of the originally deposited amorphous Si-containing material.

The thickness of the various doped Si-containing materials may vary depending upon the type of device being fabricated. In one embodiment of the present invention, and in solar cell production, p+ Si-containing material 60 has a thickness from 0.5 μm to 5 μm, the p− Si-containing material 62 has a thickness from 0.5 μm to 20 μm, and the n+ Si-containing material 64 has a thickness from 0.2 μm to 2 μm.

The structures shown in FIGS. 8A and 8B can then further processed using techniques well known to those skilled in the art into a solar cell (or photovoltaic cell). FIG. 9 is a pictorial representation (through a cross sectional view) illustrating the structure shown in FIG. SA after solar cell fabrication in accordance with an embodiment of the invention. The solar cell 100 shown in FIG. 9 includes, in addition to the structure, shown in FIG. 8A, a first metal contact 102 located atop a surface of n+ Si-containing material 64 and a second metal contact 104 atop p+ Si-containing material 60. The structure further includes via contacts 106A and 106B that extend down to a surface of p+ Si-containing material 60. Each contact includes an oxide spacer 108 as shown and a conductive material 110.

While the present invention has been particularly shown and described with respect to preferred embodiments thereof it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

1. A method of fabricating a semiconductor-on-insulator (SOI) substrate comprising:
forming a stack including a plurality of p-type doped amorphous Si-containing layers onto a major surface of a semiconductor region of a substrate, said stack including at least a first p-type doped amorphous Si-containing layer having a dopant concentration of at least 1×10¹⁹ atoms/cm³ or greater and a second p-type doped amorphous Si-containing layer located on an upper surface of the first p-type doped amorphous Si-containing layer and having a dopant concentration less than said first p-type doped amorphous Si-containing layer;
performing solid phase epitaxy on said stack of p-type doped amorphous Si-containing layers to convert said stack into a stack of single crystalline Si-containing layers including at least a first p-type doped single crystalline Si-containing layer having a dopant concentration of at least 1×10¹⁹ atoms/cm³ or greater and a second p-type doped single crystalline Si-containing layer located on an upper surface of the first p-type doped single crystalline Si-containing layer and having a dopant concentration less than said first p-type doped single crystalline Si-containing layer; and
processing the substrate including the stack of single crystalline Si-containing layers to form a buried oxide layer selectively by oxidizing at least portions of the first p-type doped single crystalline Si-containing layer covered by the second p-type doped single crystalline Si-containing layer and annealing the substrate to form a monocrystalline semiconductor layer from the second doped single crystalline Si-containing layer, wherein the buried oxide layer separates the overlying monocrystalline semiconductor layer from the underlying semiconductor region.

2. The method as claimed in claim 1, wherein said processing includes subjecting the substrate including the stack of single crystalline Si-containing layers to anodization to selectively form a porous Si-containing layer of higher porosity from the first p-type doped single crystalline Si-containing layer and a porous Si-containing layer having a lower porosity from the second p-type doped single crystalline Si-containing layer prior to oxidizing, wherein the buried oxide layer is formed by fully oxidizing the porous Si-containing layer of higher porosity and the annealing is performed at high temperature to convert the porous Si-containing layer of lower porosity to the monocrystalline semiconductor layer.

3. The method as claimed in claim 1, wherein said stack including a plurality of vertically stacked and alternating first and second p-type doped amorphous Si-containing layers.

4. The method as claimed in claim 1, further comprising forming a non-highly p-type doped amorphous Si-containing layer between said semiconductor region and said first p-type doped amorphous Si-containing layer, said non-highly p-type doped amorphous Si-containing layer having a dopant concentration less than said dopant concentration of the first p-typed doped amorphous Si-containing layer.

5. The method as claimed in claim 1, further comprising forming a highly p-type doped amorphous Si-containing layer overlying the second p-type doped amorphous Si-containing layer, wherein said highly p-type doped amorphous Si-containing layer has a doping concentration of about 1×10²⁰ atoms/cm³ or greater and protects the second p-type doped amorphous Si-containing layer from pitting during an anodization process that is performed during said processing the substrate.

6. The method as claimed in claim 1, wherein said forming said stack including the plurality of p-type doped amorphous Si-containing layers includes an evaporation deposition process selected from the group consisting of e-beam, co-evaporation deposition, plasma enhanced chemical vapor deposition, and sputtering in which the pressure during deposition is less than about 1×10⁻⁷ Torr and the temperature is about 500° C. or less, wherein said plurality of p-type doped amorphous Si-containing layers is doped in-situ.

7. (canceled)

8. The method as claimed in claim 6, wherein said forming said stack including the plurality of p-type doped amorphous Si-containing layers includes a co-evaporation method wherein simultaneous evaporation of a Si-containing source material and p-type dopant atoms is employed.

9-11. (canceled)

12. The method as claimed in claim 1, further comprising forming at least one solar cell or photovoltaic cell on a major surface of the monocrystalline semiconductor layer.

13. The method as claimed in claim 12, wherein said forming that at least one solar cell or photovoltaic cell includes forming a stack of doped Si-containing materials on said major surface of said monocrystalline semiconductor layer, wherein said stack of doped Si-containing materials includes, from bottom to top, a p+ Si-containing material, a p− Si-containing material, and an n+ Si-containing material.

14. (canceled)

15. The method as claimed in claim 13, wherein each of the doped Si-containing materials is single crystalline.

16. The method as claimed in claim 13, wherein each of the doped Si-containing materials is amorphous.

17. The method as claimed in claim 13, wherein some of said doped Si-containing materials are single crystalline, while others of said doped Si-containing materials are amorphous.

18. The method as claimed in claim 13, wherein each of said doped Si-containing materials is amorphous and is formed by an evaporation process selected from group consisting of e-beam, plasma enhanced chemical vapor deposition, and sputtering in which the pressure during deposition is less than about 1×10⁻⁷ Torr and the temperature is about 500° C. or less.

19. The method of claim 13, wherein at least one of said doped Si-containing materials is initially amorphous and is then converted to a doped single crystalline Si-containing material by solid phase epitaxy.

20. The method of claim 1, wherein said stack of p-type doped amorphous Si-containing layers is comprised of amorphous silicon layers.

21. A method of fabricating a semiconductor-on-insulator (SOI) substrate comprising:
forming a stack including a plurality of p-type doped amorphous silicon layers by a co-evaporation deposition process onto a major surface of a semiconductor region of a substrate, said stack including at least a first p-type doped amorphous silicon layer having a dopant concentration of at least 1×10¹⁹ atoms/cm³ or greater and a second p-type doped amorphous silicon layer located on an upper surface of the first p-type doped amorphous silicon layer and having a dopant concentration less than said first p-type doped amorphous silicon layer;
performing solid phase epitaxy at a temperature from 550° C. to 700° C. on said stack of p-type doped amorphous silicon layers to convert said stack into a stack of single crystalline silicon layers including at least a first p-type doped single crystalline silicon layer having a dopant concentration of at least 1×10¹⁹ atoms/cm³ or greater and a second p-type doped single crystalline silicon layer located on an upper surface of the first p-type doped single crystalline silicon layer and having a dopant concentration less than said first p-type doped single crystalline silicon layer; and
processing the substrate including the stack of single crystalline silicon layers to form a buried oxide layer selectively by oxidizing at least portions of the first p-type doped single crystalline silicon layer covered by the second p-type doped single crystalline silicon and annealing the substrate to form a monocrystalline silicon layer from the second doped single crystalline silicon layer, wherein the buried oxide layer separates the overlying monocrystalline silicon layer from the underlying semiconductor region.

22. The method as claimed in claim 21, wherein said processing includes subjecting the substrate including the stack of single crystalline silicon layers to anodization to selectively form a porous silicon layer of higher porosity from the first p-type doped single crystalline silicon layer and a porous silicon layer having a lower porosity from the second p-type doped single crystalline silicon layer prior to oxidizing, wherein the buried oxide layer is formed by fully oxidizing the porous silicon layer of higher porosity and the annealing is performed at high temperature to convert the porous silicon layer of lower porosity to the monocrystalline silicon layer.

23. The method as claimed in claim 21, wherein said stack including a plurality of vertically stacked and alternating first and second p-type doped amorphous silicon layers.

24. The method as claimed in claim 21, further comprising forming a non-highly p-type doped amorphous silicon layer between said region and said first p-type doped amorphous silicon layer, said non-highly p-type doped amorphous silicon layer having a dopant concentration less than said dopant concentration of the first p-typed doped amorphous silicon layer.

25. The method as claimed in claim 21, further comprising forming a highly p-type doped amorphous silicon layer overlying the second p-type doped amorphous silicon layer, wherein said highly p-type doped amorphous silicon layer has a doping concentration of about 1×10²⁰ atoms/cm³ or greater and protects the second p-type doped amorphous silicon layer from pitting during an anodization process that is performed during said processing the substrate.
